(19) United States
(12) Patent Application Publication
(10) Pub. No.: US 2008/0041312 A1
(43) Pub. Date: Feb. 21, 2008

(54) Stage for plasma processing apparatus, and plasma processing apparatus

(76) Inventors: Shoichiro Matsuyama, Nirasaki-Shi (JP); Shinji Himori, Nirasaki-Shi (JP); Atsushi Matsuura, Nirasaki-Shi (JP)

Correspondence Address: Smith, Gambrell & Russell, Suite 800, 1850 M Street, N.W., Washington, DC, 20036, US

(21) Appl. No.: 11/889,339

(22) Filed: Aug. 10, 2007

Related U.S. Application Data
(60) Provisional application No. 60/844,369, filed on Sep. 14, 2006.

(30) Foreign Application Priority Data
Aug. 10, 2006 (JP) 2006-217872

(51) Int. Cl. C23C 16/458

(52) U.S. Cl. 118/728

(57) ABSTRACT

[Object]To provide a stage for plasma processing apparatus, the stage being capable of improving uniformity of electric field strength in a plasma so as to enhance an in-plane uniformity of a plasma process to a substrate, and to provide a plasma processing apparatus provided with this stage. [Means for Solving the Problem]

A stage 3 for a plasma processing apparatus 2 comprises: a conductive member 31 connected to a radiofrequency power source, the conductive member serving as an electrode for generating a plasma and/or an electrode for drawing ions from a plasma; a dielectric layer 32 covering a central part of an upper surface of the conductive member, for making uniform a radiofrequency electric field applied to a plasma through a substrate to be processed wafer W) placed on the placing surface; and an electrostatic chuck 33 laminated on the dielectric layer 35, the electrostatic chuck having an electrode film embedded therein. The electrode film satisfies δ/z≧1,000 (z; a thickness of the electrode film 35, 6; a skin depth of the electrode film for the electrostatic chuck as to a radiofrequency power supplied from the radiofrequency power source).

### FIELD OF THE INVENTION

The present invention relates to: a stage for placing thereon a substrate to be processed, such as a semiconductor wafer, which is to be subjected to a plasma process; and a plasma processing apparatus including the stage.

### BACKGROUND ART

In manufacturing step of a semiconductor device, there are many steps for processing a substrate by making a process gas plasma, such as a dry etching step and an ashing step. As a plasma processing apparatus for these processes, a plasma processing apparatus of the following type is prevalently used, for example. Namely, there are disposed a pair of upper and lower parallel plate electrodes that are opposed to each other, and by applying a radiofrequency to a space between these electrodes to make plasma a process gas which has been introduced into the apparatus, a semiconductor wafer (referred to as “wafer” below) placed on the lower electrode is subjected to a plasma process.

Recently, there has been a tendency that the plasma process has to be conducted under a state in which ion energy in plasma is low, while electron density thereof is high, i.e., the “low energy and high density plasma” state is required. Thus, there is a case in which a radiofrequency of e.g., 100 MHz is used for generating a plasma, which is significantly higher than a conventional one (e.g., about 10 MHz or the like). However, when the frequency of a radiofrequency is raised, electric field strength is prone to be increased in a central region of a surface of an electrode, which region corresponds to a central region of a wafer, while the electric field strength is prone to be reduced in a circumferential region of the surface of the electrode. Such non-uniform distribution of the electric field strength causes non-uniform electron density of a plasma to be generated, whereby a processing speed varies according to a position within the wafer. Thus, a problem may occur in that a satisfactory process result as to an in-plane uniformity cannot be obtained.

In order to cope with this problem, in Patent Document 1, a dielectric layer made of ceramics or the like is embedded in a central part of a surface of one electrode, the surface facing the other electrode, so that electric field strength density is made uniform, whereby an in-plane uniformity of a plasma process can be improved.

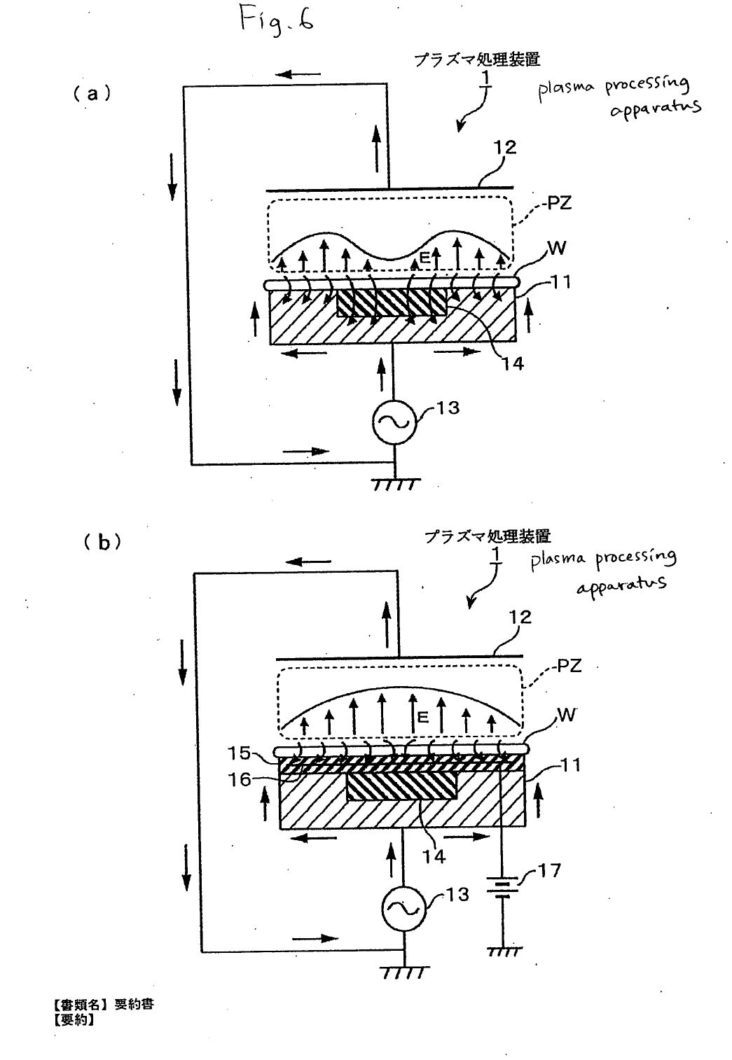

Such embedment of a dielectric layer is described with reference to FIG. 6(a). When a radiofrequency is applied to a lower electrode 11 of a plasma processing apparatus 1 from a radiofrequency power source 13, the radiofrequency is propagated through a surface of the lower electrode 11 to reach an upper part thereof by a skin effect, and then is directed to a central part along a surface of a wafer W. Herein, a part of the radiofrequency leaks to the lower electrode 11, and then flows outward inside the lower electrode 11. As compared with the other parts, the radiofrequency can more deeply plunge into a part where a dielectric layer 14 for making uniform a plasma is provided, so as to generate a hollow cylindrical resonance of TM mode. Thus, an electric field supplied from the upper surface of the wafer W to the plasma is lowered at a central part of the wafer W, to thereby make uniform the electric field within the surface of the wafer W. The reference number 12 depicts an upper electrode, and PZ depicts a plasma.

A plasma process is often conducted under a reduced pressure such as a vacuum atmosphere. In this case, as shown in FIG. 6(b), an electrostatic chuck 15 is generally used to fix the wafer W. The electrostatic chuck 15 has a structure in which a conductive electrode film 16 is interposed between upper and lower dielectric layers formed by thermally spraying, e.g., alumina. By applying high-voltage direct-current power to the electrode film 16 from a high-voltage direct-current power source 17 to generate a Coulomb force on a surface of the dielectric layer, the wafer W can be electrostatically absorbed and fixed.

However, when the wafer W is subjected to a plasma process in the state that the electrostatic chuck 15 is arranged on the lower electrode 11 having the dielectric layer 14 embedded therein for lowering electric potential of the plasma, the radiofrequency cannot transmit through the electrode film 16 in the electrostatic chuck 15, and there is generated an outward flow of the radiofrequency in the electrode film 16. In other words, because of the existence of the electrode film 16 for the electrostatic chuck, the dielectric layer 14 cannot be seen from the plasma (influence of the dielectric layer 14 on the plasma is blocked), and thus the effect by the dielectric layer 14 of lowering the electric potential of the plasma cannot be produced. As a result, an electric potential of the plasma above the central part of the wafer W becomes high, while an electric potential of the plasma above the circumferential part of the wafer W becomes low. Thus, a process speed differs between the central part of the wafer W and the circumferential part thereof, which impairs an in-plane uniformity of a plasma process such as etching.

[Patent Document 1] JP2004-363552A: page 15, sections 84 and 85

### DISCLOSURE OF THE INVENTION

[Problems to be Solve by the Invention]

Taking account of the above problem, the present invention has been made to effectively solve the same. The object of the present invention is to provide a stage for a plasma processing apparatus, the stage being capable of improving uniformity of electric field strength in a plasma so as to enhance an in-plane uniformity of a plasma process to a substrate, and to provide a plasma processing apparatus including such a stage.

[Means for Solving the Problem]

The present invention is a stage for a plasma processing apparatus, the stage being configured to place on a placing surface thereof a substrate to be processed, the stage comprising: a conductive member connected to a radiofrequency power source, the conductive member serving as an electrode for generating a plasma and/or an electrode for drawing ions from a plasma; a dielectric layer covering a central part of an upper surface of the conductive member, for making uniform a radiofrequency electric field applied to a plasma through a substrate to be processed placed on the placing surface; and an electrostatic chuck laminated on the dielectric layer, the electrostatic chuck having an electrode film embedded therein.
δ/z≧1,000,

wherein δ=(2/ωμσ)^{1/2}, ω=2πf, σ=1/ρ,

wherein z; a thickness of the electrode film for the electrostatic chuck, δ; a skin depth of the electrode film for the electrostatic chuck as to a radiofrequency power supplied from the radiofrequency power source, f; frequency of a radiofrequency power supplied from a radiofrequency power source, π; a circular constant, μ; a magnetic permeability of the electrode film for the electrostatic chuck, and ρ; a resistivity of the electrode film for the electrostatic chuck.

The dielectric layer may be formed into a columnar shape to generate a hollow cylindrical resonance of TM mode. A thickness of a circumferential part of the dielectric layer may be smaller than a thickness of a central part of the dielectric layer. A frequency of the radiofrequency supplied from the radiofrequency power source is not less than 13 MHz.

[Effect of the Invention]

According to the present invention, since the expression δ/z≧1,000 is satisfied, the radiofrequency propagated through the substrate to be processed can pass through the electrode film to plunge into a lower part of the dielectric layer for making uniform a radiofrequency electric field applied to the plasma through the substrate to be processed. As a result, even when there is disposed the electrostatic chuck, by utilizing the dielectric layer to generate a hollow cylindrical resonance of TM mode, it is possible to lower the electric field in a central part which is supplied from the upper surface of the substrate to be processed to the plasma. Namely, in the electric field strength distribution, it is possible to flatten a chevron-like area of a high electric field strength. As a result, an in-plane uniformity of a plasma process, such as an etching process, can be enhanced.

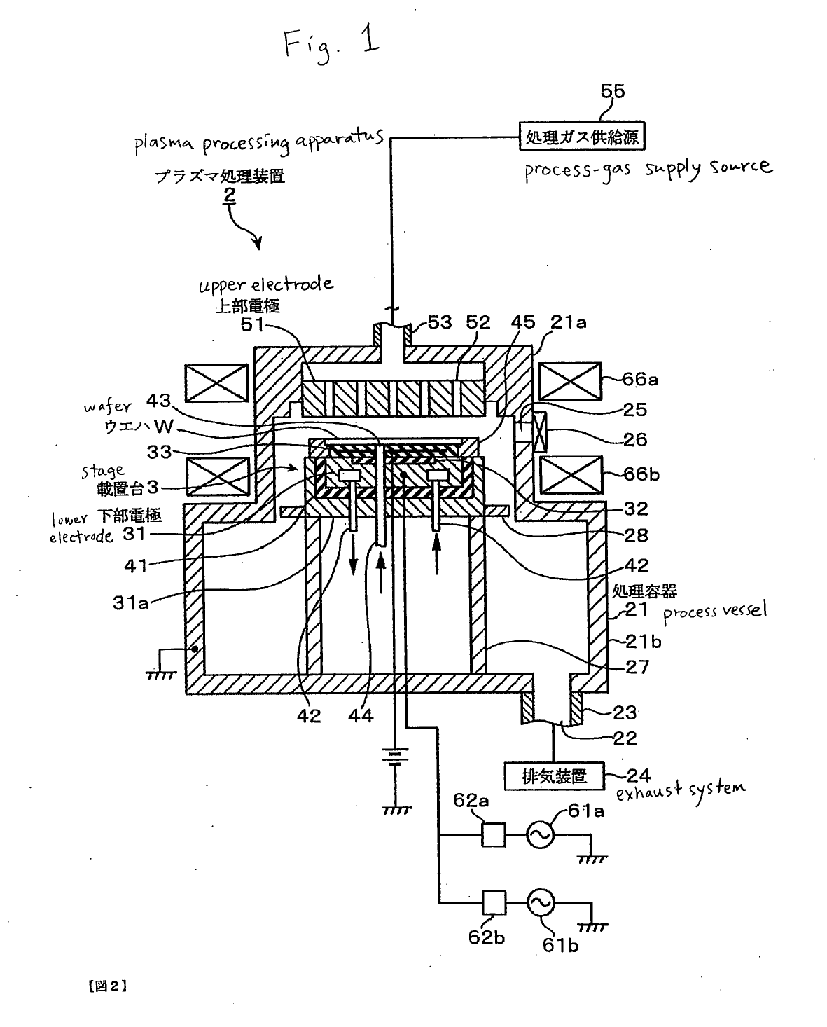

An embodiment of the stage according to the present invention, which is applied to an etching apparatus as a plasma processing apparatus, is described with reference to FIG. 1. A plasma processing apparatus 2 shown in FIG. 1 is a RIE (Reactive Ion Etching) plasma processing apparatus. The plasma processing apparatus 2 includes: a process vessel 21 of a vacuum chamber, an inside of which is a hermetically sealed space; a stage 3 disposed on a central part of a bottom surface of the process vessel 21; and an upper electrode 51 which is disposed above the stage 3 and opposed thereto.

The process vessel 21 has a cylindrical upper chamber 21a of a smaller diameter, and a cylindrical lower chamber 21b of a larger diameter. The upper chamber 21a and the lower chamber 21b are communicated with each other, and the overall process vessel 21 can be air-tightly closed. The upper chamber 21a contains the stage 3, the upper electrode 51, and so on. The lower chamber 21b contains a support case 27 that supports the stage 3 and houses pipes or the like. An exhaust system 24 is connected via an exhaust pipe 23 to an exhaust port 22 formed in a bottom surface of the lower chamber 21b. A pressure adjusting part, not shown, is connected to the exhaust system 24. Based on a signal from a control part, not shown, the pressure adjusting part is configured to evacuate the whole inside of the process vessel 21, and to maintain the same at a desired vacuum degree. A loading/unloading port 25 for a wafer W as a substrate to be processed is formed in a side surface of the upper chamber 21a. The loading/unloading port 25 is capable of being opened and closed by a gate valve 26. The process vessel 21 is formed of a conductive material such as aluminum, and is grounded.

The stage 3 includes: a lower electrode 31 for generating a plasma, which is a conductive member made of, e.g., aluminum; a dielectric layer 32 for adjusting an electric field to be uniform, the dielectric layer 32 being embedded in the lower electrode 31 to cover a central part of an upper surface of the lower electrode 31; and an electrostatic chuck 33 for fixing a wafer W. The lower electrode 31, the dielectric layer 32, and the electrostatic chuck 33 are stacked in this order from below. The lower electrode 31 is secured on a support table 31a disposed on the support case 27, via an insulating member 41, and in a sufficiently electrically floating situation relative to the process vessel 21.

A cooling medium passage 42 through which a cooling medium passes is formed in the lower electrode 31. When the cooling medium flows in the cooling medium passage 42, the lower electrode 31 is cooled. Thus, a wafer W placed on a placing surface can be cooled to a desired temperature.

The electrostatic chuck 33 is provided with a through-hole 43 for discharging a heat-conductive backside gas for elevating heat transfer rate between a surface of the electrostatic chuck 33 on which a wafer W is placed, i.e., a placing surface, and a rear surface of the wafer W. The through-hole 43 is communicated with a gas passage 44 formed in the lower electrode 31. A backside gas such as helium (He), which has been supplied through the gas passage 44 from a gas supply part, not shown, is discharged from the through-hole 43.

To the lower electrode 31, there are connected a first radiofrequency power source 61a and a second radiofrequency power source 61b via matching boxes 62a and 62b, respectively. The first radiofrequency power source 61a supplies a radiofrequency of, e.g., 100 MHz, and the second radiofrequency power source 61b supplies a radiofrequency of, e.g., 3.2 MHz which is lower than the radiofrequency supplied from the first radiofrequency power source 61a. As described below, the radiofrequency supplied from the first radiofrequency power source 61a serves to make a process gas plasma. The radiofrequency supplied from the second radiofrequency power source 61b serves to apply a bias electric power to a wafer W so as to draw ions from a plasma into a surface of the wafer W.

A focus ring 45 is arranged on a periphery of the upper surface of the lower electrode 31 to surround the electrostatic chuck 33. The focus ring 45 functions to adjust a condition of a plasma in a region outside the circumference (edge) of the wafer W. To be specific, by making larger an area of the plasma than that of the wafer W, the focus ring 45 further elevates uniformity in etching speed in a plane of the wafer.

A baffle plate 28 is disposed on an outside surface of a lower part of the support table 31a. A process gas in the upper chamber 21a flows into the lower chamber 21b through a clearance formed between the baffle plate 28 and a wall of the upper chamber 21a. Namely, the baffle plate 28 serves as a current plate for rectifying the process gas.

The upper electrode 51 is formed hollow. In a lower surface of the upper electrode 51, a large number of gas-supplying holes 52 are formed in a uniformly dispersed manner, for example, for dispersedly supplying a process gas into the process vessel 21, to thereby constitute a gas shower head. A gas-introducing pipe 53 is disposed on a central part of an upper surface of the upper electrode 51. The gas-introducing pipe 53 passes through a central part of an upper surface of the process vessel 21, and is connected to a process-gas supplying source 55 on an upstream side. The process-gas supplying source 55 has a not-shown control mechanism for controlling a feed rate of a process gas. Thus, feed ON/OFF of a process gas to the plasma processing apparatus 2, and increase/decrease of a feed rate of the process gas can be controlled. Since the upper electrode 51 is secured on a wall part of the upper chamber 21a, a conductive path is formed between the upper electrode 51 and the process vessel 21.

Two multipole ring magnets, i.e., an upper multipole ring magnet 66a and a lower multipole ring magnet 66b are arranged around the upper chamber 21a such that the gate valve 26 is positioned between the multipole ring magnets 66a and 66b. Each of the multipole ring magnets 66a and 66b is formed of a plurality of anisotropic segment columnar magnets which are attached to a ring-shaped magnetic casing. Magnetic poles of the adjacent segment columnar magnets are oriented in the mutually reverse direction. Owing to this arrangement, lines of magnetic force are formed between the adjacent segment magnets, and a magnetic field is formed in an area surrounding a process space between the upper electrode 51 and the lower electrode 31, so that a plasma can be confined within the process space. However, it is possible to adopt a structure of the apparatus which does not have the multipole ring magnets 66a and 66b.

By the above structure of the apparatus, a pair of parallel plate electrodes are formed by the lower electrode 31 and the upper electrode 51, in the process vessel 21 (upper chamber 21a) of the plasma processing apparatus 2. After the inside of the process vessel 21 is adjusted at a predetermined pressure, by supplying radiofrequencies from the radio frequency power sources 61a and 61b, while a process gas is introduced into the process vessel 21, the process gas is made plasma. The radiofrequencies flow through the lower electrode 31, the plasma, the upper electrode 51, the wall part of the process vessel 21, and an earth, in this order. By means of this operation of the plasma processing apparatus 2, the wafer W fixed on the stage 3 is subjected to an etching by the plasma.

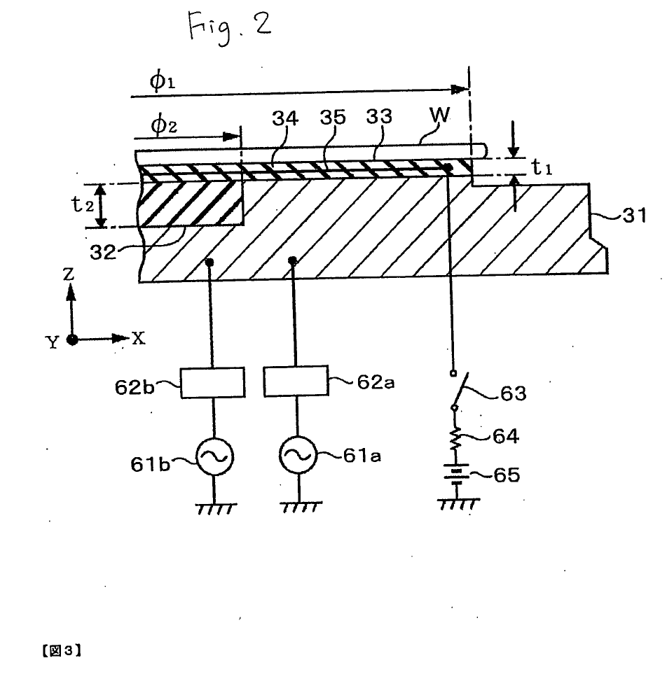

With reference to FIG. 2, the stage 3 in this embodiment is described in detail below. In the longitudinal sectional view of the stage 3 shown in FIG. 2, illustration of the cooling medium passage 42, the gas passage 44 for a backside gas, and so on are omitted.

As described above, the dielectric layer 32 is embedded in a central part of an upper surface of the lower electrode 31. The dielectric layer 32 has a function for lowering an electric potential of a plasma in a range where the dielectric layer 32 is embedded. For example, the dielectric layer 32 is made of ceramics containing alumina (Al₂O₃) as a principal component and having a dielectric constant of 10. The dielectric layer 32 is of a columnar shape having a thickness t₂=5 mm and a diameter Φ₂=100 mm.

Next, the electrostatic chuck 33 is described. The electrostatic chuck 33 has a diameter substantially the same as that of an upper surface of the lower electrode 31, a thickness of 1 mm, and a discoid shape as a whole. The electrostatic chuck 33 has a structure in which an electrode film 35 is interposed between upper and lower dielectric layers 34. The dielectric layers 34 of the electrostatic chuck 33 are formed on the electrode film 35 by thermally spraying ceramics having a dielectric constant of about 8.

The electrode film 35 is formed of an electrode material of alumina (Al₂O₃) containing 35 wt % of molybdenum carbide (MoC). A thickness of the electrode film 35 is 15 μm, and a resistivity thereof is 30 Ωcm. The electrode film 35 is connected to a high-voltage direct-current power source 65 via a switch 63 and a resistance 64. When a high-voltage direct-current electric power is applied from the high-voltage direct-current power source 65 to the electrode film 35, a Coulomb force is generated on a surface of the dielectric layer 34 of the electrostatic chuck 33. Due to the thus generated Coulomb force, a wafer W is electrostatically absorbed on the upper surface, i.e., the placing surface of the electrostatic chuck 33.

Lest a radiofrequency current fails to transmit through the electrode film 35 to prevent exertion of the effect produced by the embedded dielectric layer 32, the electrode film 35 embedded in the electrostatic chuck 33 is structured to satisfy the following condition.
δ/z≧1,000

wherein δ=(2/ωμσ)^{1/2}, ω=2πf, and σ=1/ρ.

wherein z; a thickness [m] of the electrode film 35, δ; a skin depth [m] of the electrode film 35 as to a radiofrequency power supplied from the radiofrequency power source 61a, f; frequency of a radio frequency power supplied from a radiofrequency power source 61a, π; a circular constant, μ; a magnetic permeability [H/m] of the electrode film 35, and ρ; a resistivity [Ωm] of the electrode film 35.

The reason why the above conditions are preferred for the electrode film 35 of the electrostatic chuck 33 is described below.

An electric field E and a magnetic flux density D formed by a radiofrequency power in the electrode film 35 satisfy the following (Expression 1) and (Expression 2) according to the Maxwell equations.
∇×H=∂D/∂t+σE (Expression 1)
∇×E=−μ(∂H/∂t) (Expression 2)

Then, the above expressions are solved with a thickness direction of the electrode film 35 being taken in a z-axis and a side of the lower electrode 31 being taken positive, so that an electric field strength in the z-axis direction is expressed by the following (Expression 3).
E=E₀exp(−iωt)exp(iKz) (Expression 3)

Herein, E₀ is an electric field strength of an electric field incident on the electrode film 35, and K is a parameter expressed by the following (Expression 4).
K=(ωμσ/2)^{1/2}+i (ωμσ/2)^{1/2} (Expression 4)

When the above (Expression 3) is re-expressed by using the (Expression 4), the following (Expression 5) is provided.
E=E₀exp(−iωt)exp{i(ωμσ/2)^{1/2}z}exp{−(ωμσ/2)¹²z} (Expression 5)

The value “(2/ωμσ)^{1/2}” corresponds to the skin depth of the electrode film 35 as to a radiofrequency power. Thus, by replacing the value with “δ” as in the following (Expression 6), the following (Expression 7) is provided.
δ=(2/ωμσ)^{1/2} (Expression 6)
E=E₀exp(−iωt)exp(iz/δ)exp(−z/δ) (Expression 7)

By manipulating (Expression 7), a transmittance “E/E₀” at which an electric field of a radiofrequency power transmits the electrode film 35 is in proportion to “exp(−z/δ)” as shown in the following (Expression 8). In other words, as the value “z/δ” comes closer to “0”, the transmittance of an electric field comes closer to 1.0 (100%).
E/E₀∝exp(−z/δ) (Expression 8)

That is to say, when a value “δ/z” which is the inverse number of the “z/δ” is increased, the transmittance of an electric field is raised accordingly. Thus, when the skin depth “δ=(2/ωμσ)^{1/2}” with respect to the thickness “z” of the electrode film 35 is relatively increased, it is possible to allow almost all the radiofrequency current from the wafer W to transmit through the electrode film 35 toward the dielectric layer 32. In order thereto, when a frequency is constant, the value “δ/z” can be increased by using an electrode material having a large resistivity “ρ=1/σ” (having a small conductivity “σ”). Alternatively, the value “δ/z” can be also increased by reducing the thickness “z” of the electrode film 35.

Further, the higher the frequency of a radiofrequency power is, the smaller the skin depth is (δ∝(1/ω)^{1/2}=(1/2πf)^{1/2}). Thus, when the frequency of a radiofrequency power is raised, an electrode material having a larger resistivity has to be used in order to negate influence of the radiofrequency power.

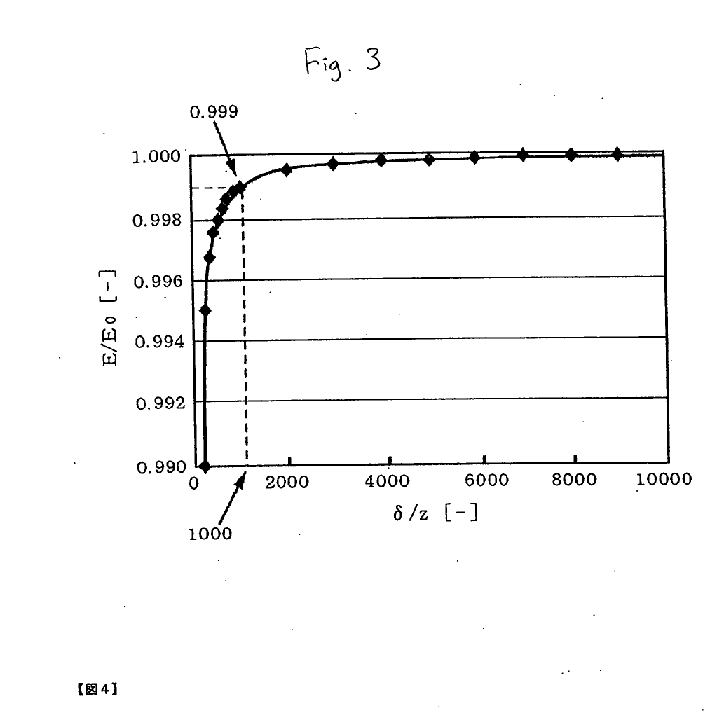

FIG. 3 is a graph in which transmittances E/E₀ at which an electric field transmits through the electrode film 35 are plotted, the transmittances E/E₀ being calculated with the “δ/z” as a parameter. As understood from FIG. 3, when the “δ/z” is not less than 1,000, it is possible to make a transmittance of an electric field be “not less than 0.999” (not less than 99.9%). It is considered that, when 99.9% or more of the electric field can transmit through the electrode film 35, the dielectric layer 32 embedded in the lower electrode 31 can give sufficient influences on a plasma, so that it is possible to exert the effect of lowering an electric potential of a plasma in a range where the dielectric layer 32 is embedded.

An operation of the stage 3 in this embodiment is described below. A part of the radiofrequency current, which has been supplied from the first radiofrequency power source 61a and propagated through the surface of the lower electrode 31, leaks from the surface of the wafer W to the electrostatic chuck 33. Since the electrode film 35 embedded in the electrostatic chuck 33 is structured to satisfy the condition “δ/z≧1,000”, 99.9% ormore of the radiofrequency current which has been incident on the electrode film 35 is allowed to transmit therethrough. As a result, the radiofrequency current can reach the dielectric layer 32. Therefore, in a region where the dielectric layer 32 is embedded, the radiofrequency can plunge more deeply as compared with the other regions, so that an effect of lowering an electric potential of a plasma in the region can be obtained.

By the operation as described above, even the stage 3 of a type using the electrostatic chuck 33 for fixing a wafer W can provide an effect of lowering an electric potential of a plasma with the use of the dielectric layer 32. Unless the dielectric layer 32 exerts the effect, the electric field strength distribution has a chevron-shaped peak. However, due to exercitation of the effect of the dielectric layer 32, the peak in the electric field strength distribution can be flattened. Thus, an excellent uniformity of electron density in a plasma can be obtained, and an in-plane uniformity of a plasma process such as an etching process can be significantly improved.

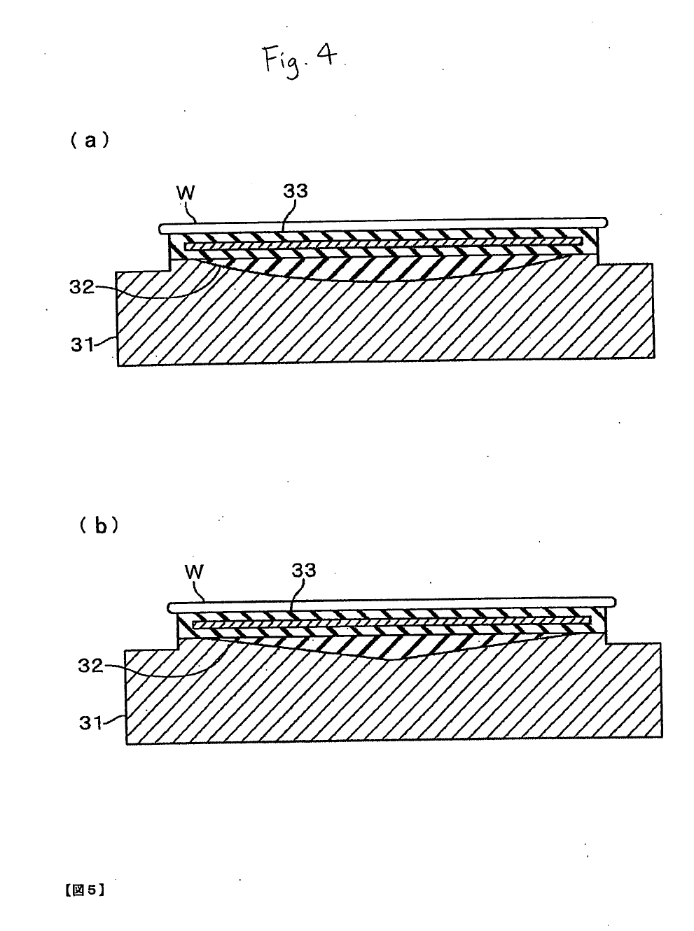

A shape of the dielectric layer 32 is not limited to the columnar shape as in the above embodiment. For example, the dielectric layer 32 may be of a domed shape as shown in FIG. 4(a) or a circular conic shape as shown in FIG. 4(b). By making a thickness of the circumferential part of the dielectric layer 32 smaller than that of the central part thereof, the electric field strength is more weakened in the central part than in the circumferential part, so that a more flattened electric filed distribution can be obtained.

The structure of the electrostatic chuck 33 is not limited to the type in which a dielectric layer made of thermally sprayed alumina is used to generate the Coulomb force. For example, the present invention may be applied to an electrostatic chuck using a ceramic plate made of aluminum nitride as a dielectric layer in which an electrode film is embedded. This type of electrostatic chuck is often joined to the lower electrode 31 by an adhesive. In this case, it is preferable to use an adhesive having a large resistivity so as to allow a radiofrequency current from the surface of a wafer W to transmit through the layer of the adhesive (adhesive layer).

Further, since a general coefficient of linear expansion of ceramics, which is used as a dielectric layer, is 2×10⁻⁶/° C. to 11×10⁻⁶/° C., it is preferable to select a conductive member whose coefficient of linear expansion is approximate to the above value, for forming an electrode.

### EXAMPLES

Influences given to actual plasma processes by the differences in structure of the different electrostatic chuck 33 of the stages 33 were examined.

A. Experiment Method

In this experiment, there were used plasma processing apparatuses of a parallel plate type as shown in FIG. 1 which respectively incorporated the stages 3 having the structures as those shown in Reference Example, Example 1, and Comparative Example 1.

At first, a wafer W on which a resist film had been applied was placed on a placing surface of each stage 3, and a plasma was generated to ash the resist film. A pressure in the process vessel 21 was 0.7 Pa (5 mTorr). An O₂ gas (supplied at 100 sccm) was used as a process gas. A radiofrequency for generating plasma has a frequency of 100 MHz, and a power of 2 kW. After the ashing process was performed for a predetermined period of time, ashing speeds per unit time were calculated by measuring a thickness of the resist film at predetermined measuring points on the wafer W.

### Reference Example

A stage which did not have the electrostatic chuck 33 and the electrode film 35 was prepared as Reference Example.

### Example 1

An electrode film 35 which satisfied the condition of “δ/z≧1,000” (for example, δ/z=1837.8), was manufactured by using an electrode material (alumina (Al₂O₃) containing 35 wt % of MoC) having a resistivity of 30 Ωcm and a thickness of 15 μm. A stage having an electrostatic chuck 33 including the thus manufactured electrode film 35 was prepared as Example 1. A basic structure of the stage was identical to the structure described with reference to FIG. 2, excluding the conditions of the electrode film 35. Namely, the embedded dielectric layer 32 had a thickness t₂=5 mm and a diameter Φ₂=100 mm.

### Comparative Example 1

An electrode film 35 which did not satisfy the condition of “δ/z≧1,000” (for example, δ/z=33.6), was manufactured by using an electrode material (alumina (Al₂O₃) containing 40 wt % of MoC) having a resistivity of 0.01 ωcm and a thickness of 15 μm. A stage having an electrostatic chuck 33 including the thus manufactured electrode film 35 was prepared as Comparative Example 1. A basic structure of the stage was identical to the structure described with reference to FIG. 2, excluding the conditions of the electrode film 35. Namely, the embedded dielectric layer 32 had a thickness t₂=5 mm and a diameter Φ₂=100 mm.

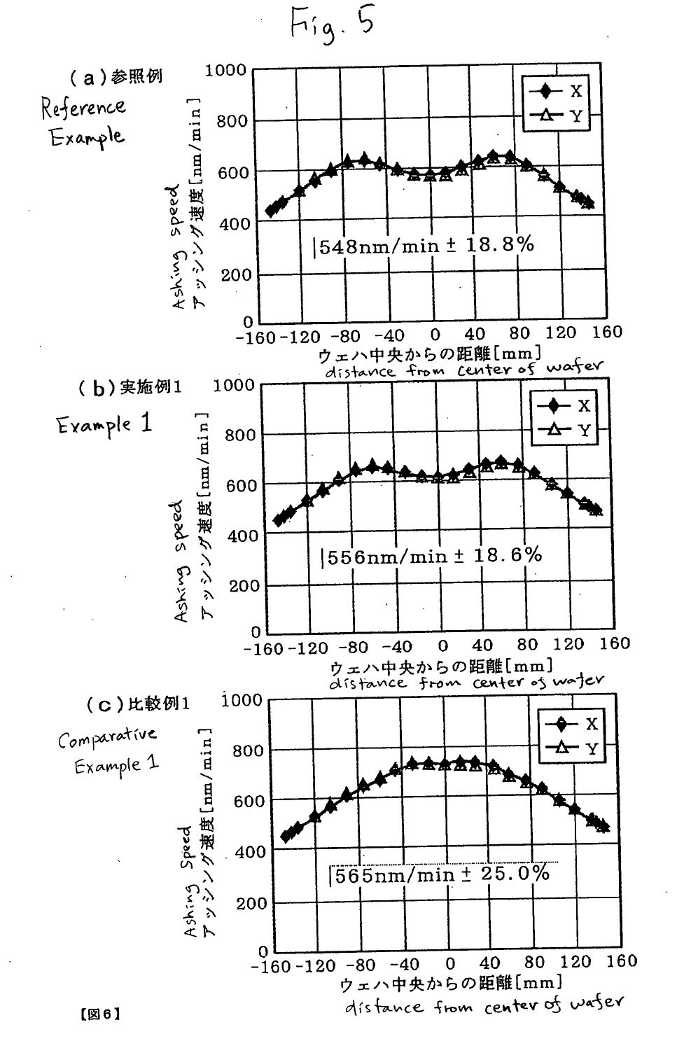

FIG. 5 shows results in which ashing speeds calculated by the experiment results for each measuring point on the wafer W are plotted. FIG. 5(a) shows the experiment results of Reference Example, FIG. 5(b) shows the experiment results of Example 1, and FIG. 5(c) shows the experiment results of Comparative Example 1. The horizontal axis of each graph shows a distance [mm] of the wafer W from a center of the wafer W, when coordinate axes are set in the directions shown in FIG. 2, i.e., in an X-axis direction (right and left direction in the view, with the right side being positive) and in a Y-axis direction (a direction from front to behind in the view, with the behind side being positive). The vertical axis in each graph shows an ashing speed [nm/min]. In the respective experiment results, an ashing speed in the X-axis direction is plotted by rhombi (♦), and an ashing speed in the Y-axis direction is plotted by triangles (Δ). The numbers described in each graph show an average value of an ashing speed under each experiment condition, and a relative variation width [%] of the experiment result relative to the average value.

In view of the experiment results, in all the conditions (Reference Example, Example 1, Comparative Example 1), no difference in ashing speed was found depending on the X-axis direction and the Y-axis direction, i.e., the ashing speed distribution was radially symmetric relative to the center of the wafer W. In view of the experiment results of Reference Example, as shown in FIG. 5(a), no peak of the ashing speed was found at the central region of the wafer W. Namely, it can be said that, since the electrostatic chuck was not disposed, i.e., there is no electrode film disposed between the wafer W and the dielectric layer 32, the dielectric layer 32 embedded in the lower electrode 31 could act on the plasma, so that the effect of lowering an electric potential of a plasma in the region where the dielectric layer 32 was embedded could be obtained, and therefore, a peak in the electric field strength distribution, which may draw a chevron-like curve without the effect of the dielectric layer 32, could be flattened.

In view of the experiment results of Example 1, as shown in FIG. 5(b), the shape of the ashing speed distribution and the variation width relative to the average value were substantially the same as the experiment results of Reference Example. Namely, it can be said that, even when there was disposed the electrode film 35 between the wafer W and the dielectric layer 32, since the electrode film 35 satisfied the condition ”δ/z≧1,000”, the dielectric layer 32 embedded in the lower electrode 31 could act on the plasma, so that the effect of lowering an electric potential of a plasma in the region where the dielectric layer 32 was embedded could be obtained, and therefore, a peak in the electric field strength distribution, which may draw a chevron-like curve without the effect of the dielectric layer 32, could be flattened.

On the other hand, in view of the experiment results of Comparative Example 1, as shown in FIG. 5(c), the ashing speed distribution took a chevron-like shape in which the ashing speed became maximum at the central region of the wafer W. In addition, the variation width relative to the average value of the ashing speed was as large as 25%, as compared with the variation widths of Reference Example and Example 1 (18.6% to 18.8%), resulting in an inferior in-plane uniformity. Namely, it can be said that, with the use of the electrostatic chuck 33 in which the electrode film 35 that did not satisfy the condition “δ/z≧1,000” was embedded, the dielectric layer 32 embedded in the lower electrode 31 could not act on the plasma, so that the effect of lowering an electric potential of the plasma in the region where the dielectric layer 32 was embedded could not be produced.

### BRIEF DESCRIPTION OF THE DRAWINGS

[FIG. 1] A schematic longitudinal sectional view of a plasma processing apparatus including a stage according to a first embodiment of the present invention.

[FIG. 2] A schematic longitudinal sectional view of the stage in the first embodiment of the present invention.

[FIG. 3] A graph in which transmittances E/E₀ at which an electric field transmits through an electrode film are plotted, the transmittances E/E₀ being calculated with 8/z as a parameter.

[FIG. 4] A longitudinal side view showing an example of a modification of the stage.

[FIG. 5] A graph showing results of example conducted for confirming the effect of the present invention.

[FIG. 6] A view illustrating a conventional plasma processing apparatus provided with a stage.

### DESCRIPTION OF REFERENCE NUMBERS

PZ plasma
W wafer
2 plasma processing apparatus
3 stage
21 process vessel
21a upper chamber
21b lower chamber
22 exhaust port
23 exhaust pipe
24 exhaust system
25 loading/unloading port
26 gate valve
27 support case
28 baffle plate
31 lower electrode
31a support table
32 dielectric layer
33 electrostatic chuck
34 dielectric layer
35 electrode film
41 insulating member
42 coolant medium passage
43 through-hole
44 gas passage
45 focus ring
51 upper electrode
52 gas-supplying hole
53 gas-introducing pipe
55 process-gas supplying source
61a first radiofrequency power source (radiofrequency power source)
61b second radiofrequency power source
62a, 62b matching box
63 switch
64 resistance
65 high-voltage direct-current voltage
66a, 66b multipole ring magnet

1. A stage for a plasma processing apparatus, the stage being configured to place on a placing surface thereof a substrate to be processed, the stage comprising:
a conductive member connected to a radiofrequency power source, the conductive member serving as an electrode for generating a plasma and/or an electrode for drawing ions from a plasma;
a dielectric layer covering a central part of an upper surface of the conductive member, for making uniform a radiofrequency electric field applied to a plasma through a substrate to be processed placed on the placing surface; and
an electrostatic chuck laminated on the dielectric layer, the electrostatic chuck having an electrode film embedded therein.
δ/z≧1,000,
wherein δ=(2/ωμσ)^{1/2}, ω=2πf, σ=1/ρ,
wherein z; a thickness of the electrode film for the electrostatic chuck, δ; a skin depth of the electrode film for the electrostatic chuck as to a radiofrequency power supplied from the radiofrequency power source, f; frequency of a radiofrequency power supplied from a radiofrequency power source, π; a circular constant, μ; a magnetic permeability of the electrode film for the electrostatic chuck, and ρ; a resistivity of the electrode film for the electrostatic chuck.

2. The stage for a plasma processing apparatus according to claim 1,
wherein the dielectric layer is formed into a columnar shape.

3. The stage for a plasma processing apparatus according to claim wherein a thickness of a circumferential part of the dielectric layer is smaller than a thickness of a central part of the dielectric layer.

4. The stage for a plasma processing apparatus according to one of claims 1 to 3,
wherein a frequency of the radiofrequency supplied from the radiofrequency power source is not less than 13 MHz.

5. A plasma processing apparatus comprising:
a process vessel configured to subject a substrate to be processed to a plasma process;
a process-gas introducing part for introducing a process gas into the process vessel;
the stage for a plasma processing apparatus according to one of claims 1 to 4, the stage being disposed in the process vessel;
an upper electrode disposed in the process vessel, the upper electrode being positioned above the stage and opposed thereto; and
a unit for evacuating an inside of the process vessel to create therein a vacuum.
